(19) United States
(12) Patent Application Publication
(10) Pub. No.: US 2026/0050039 A1
(43) Pub. Date: Feb. 19, 2026

(54) BATTERY CHARACTERISATION

(71) Applicant: Nordic Semiconductor ASA, Trondheim (NO)

(72) Inventors: Tharaka KAUSHALYA, Oulu (FI); Markus Petteri LITTOW, Oulu (FI)

(73) Assignee: Nordic Semiconductor ASA, Trondheim (NO)

(21) Appl. No.: 19/103,507

(22) PCT Filed: Aug. 17, 2023
(86) PCT No.: PCT/EP2023/072681

§ 371 Date: Feb. 12, 2025

(30) Foreign Application Priority Data
Aug. 17, 2022 (GB) 2212011.7

(51) Int. Cl. G01R 31/367; G01R 31/374; G01R 31/3842; H01M 10/44; H01M 10/48; H02J 7/00

(52) U.S. Cl. CPC G01R 31/367; G01R 31/374; G01R 31/3842; H01M 10/44; H01M 10/486; H01M 10/488; H02J 7/00712

(57) ABSTRACT

A battery characterisation system for determining one or more characteristics of a battery is provided. The system comprises a controllable load arranged to be connected to a battery and a voltage sensor arranged to measure a voltage output from said battery. The battery characterisation system is arranged to receive information identifying one or more nominal properties of said battery; to select a discharge profile based on said one or more nominal properties; to control the controllable load to discharge said battery according to said discharge profile; to record the voltage output measured by the voltage sensor and a current output from the battery as the battery is being discharged; and to determine one or more characteristics of the battery using said recorded voltage output and current output.

### BACKGROUND OF THE INVENTION

The present invention relates to methods and systems for characterising a battery. Battery-powered devices are very common. It is useful to be able to assess the state of charge (SOC) of the battery in such devices, for instance to estimate how much longer the device can operate for before the energy stored in the battery is depleted.

Estimating the SOC of a battery typically requires knowledge of battery characteristics, such as open circuit voltage and internal resistance, in different operating conditions (e.g. at different temperatures or at different states of charge).

This information may be used to build a model of the battery (e.g. an equivalent circuit model or ECM) that can then be used to estimate the SOC. This information can be gathered with a process of battery characterisation.

Current approaches to battery characterisation involve a number of laboratory tests carried out at various operating temperatures, e.g., repeatedly discharging a battery under varying conditions. This can be very time consuming and expensive, requiring expensive equipment and hundreds of hours to characterise a single battery. Therefore, users requiring battery characteristics must either engage the services of an external testing company or rely on generic published characteristics for the battery chemistry in question. However, testing companies can be expensive and inconvenient, and generic information may not be accurate for the specific battery used.

An improved approach to battery characterisation may be desired.

### SUMMARY OF THE INVENTION

According to a first aspect of the present invention there is provided a battery characterisation system for determining one or more characteristics of a battery comprising:
a controllable load arranged to be connected to a battery; and
a voltage sensor arranged to measure a voltage output from said battery; wherein the battery characterisation system is arranged to:
receive information identifying one or more nominal properties of said battery
select a discharge profile based on said one or more nominal properties;
control the controllable load to discharge said battery according to said discharge profile;
record the voltage output measured by the voltage sensor and a current output from the battery as the battery is being discharged; and
determine one or more characteristics of the battery using said recorded voltage output and current output.

According to a second aspect of the present invention there is provided a method of characterising a battery comprising:
receiving information identifying one or more nominal properties of a battery;
selecting a discharge profile based on said one or more nominal properties;
controlling a load connected to a battery to discharge said battery according to said discharge profile;
recording a voltage output from said battery and a current output from said battery during said discharging; and
determining one or more characteristics of the battery using said recorded voltage output and current output.

According to a third aspect of the present invention there is provided computer software comprising instructions that, when executed by a processing system, cause the processing system to:
receive information identifying one or more nominal properties of a battery
select a discharge profile based on said one or more nominal properties;
control a controllable load to discharge said battery according to said discharge profile;
record a voltage output from said battery and a current output from aid battery as the battery is being discharged; and
determine one or more characteristics of the battery using said recorded voltage output and current output.

Thus, it will be appreciated by those skilled in the art that the battery can be characterised relatively quickly and cheaply because one or more characteristics of the battery are determined with only one discharge cycle. Selecting the discharge profile based on nominal battery properties means that the battery can be discharged in a way that is optimised for gathering information useful for determining the one or more battery characteristics. This may enable the characteristic(s) of the battery to be determined more accurately and/or more quickly.

The battery characterisation system provides a convenient solution for battery characterisation without requiring specialist and expensive equipment and long testing times. Whilst determining battery characteristics using data collected during only one discharge of the battery may not necessarily be as accurate as conventional methods requiring multiple discharges, the inventors have recognised that this may still provide more accurate results than using generic characteristics (e.g. generic battery models based on the battery chemistry).

The controllable load may comprise a resistive load, e.g. a variable resistor. In such embodiments, the resistance may be varied to control the load. The controllable load may comprise a controllable current sink (e.g. that regulates a voltage applied across a known resistance). In some embodiments, the controllable load may be controlled to apply a series of different loads to the battery to generate the desired discharge profile.

The current output from the battery may be estimated using the controllable load. For instance, in embodiments using a resistive load, a current output from the battery may be calculated using a resistance of the controllable load and the measured voltage output from the battery (e.g. using Ohm's law). In embodiments featuring a controllable current sink, the current output may be assumed to be equal to the designed current load of the current sink.

In some embodiments, the battery characterisation system comprises a current sensor arranged to measure the current output from the battery. The current sensor may be part of the controllable load or may be provided separately.

The one or more nominal properties based on which the discharge profile is selected may comprise published or specified properties of the battery, i.e. properties the battery is designed or intended to have. For instance, the one or more nominal properties may comprise a nominal capacity, a discharge cutoff voltage, a charge cutoff voltage, a nominal voltage, a charge termination current and/or a battery chemistry. In some embodiments, the one or more nominal properties are used when determining the one or more characteristics.

One or more nominal properties of the battery may be known to the battery characterisation system in advance (e.g. stored in a memory of the battery characterisation system). In such embodiments, the information identifying the one or more nominal properties may comprise the type or model of battery (e.g. a battery chemistry or a model number). One or more nominal properties associated with the type or model of battery may then be retrieved.

Additionally or alternatively, the one or more nominal properties of the battery may be received directly (e.g. from an external source such as a user). In a set of embodiments, the battery characterisation system comprises a user interface. The user interface may be arranged to receive the information identifying the one or more nominal properties from a user (e.g. arranged to allow a user to input one more nominal properties and/or to select one more nominal properties stored in a memory of the battery characterisation system.

The battery characterisation system may comprise a network interface (e.g. an internet interface) for receiving one or more nominal properties from another device or system (e.g. a remote internet server). For example, a user may specify a battery type or model and then the system may retrieve one or more nominal properties associated with said battery type or model from an external source such as a remote internet server.

Recording the voltage output and/or the current output may comprise producing a time series of voltage and/or current information (e.g. a time-stamped record of the voltage output and/or current output as the battery is discharged). The way in which the voltage output and/or the current output changes over time as the battery is discharged (e.g. gradients, maxima, minima) may be analysed to determine the one or more characteristics.

The battery may comprise a single battery cell, or part or all of a battery pack (e.g. one or more cells of a battery pack).

The one or more characteristics of the battery determined using said recorded voltage output and current output may be suitable for determining one or more parameters of a battery model. In some embodiments, the one or more characteristics are one or more parameters of the battery model. Producing an accurate model of a particular battery may be very useful, e.g. for estimating the battery's SOC, state of health (SOH) and/or predicting its behaviour (e.g. the battery voltage response to a given current stimulus). In a set of embodiments, the one or more characteristics comprise parameters of a battery equivalent circuit model (ECM), e.g. an open circuit voltage, an internal resistance and/or parameters of one or more other components such as an RC network.

The one or more characteristics may be determined using a regression analysis technique, e.g. a least squares or “curve fitting” approach. For instance, the one or more characteristics may be determined by minimising an error between a modelled voltage output and/or current output and the recorded voltage output and/or current output. Additionally or alternatively, the one or more characteristics may be determined using other techniques such as machine learning.

The one or more characteristics may be determined directly from the voltage output and current output recorded during the entire discharging. For instance, the one or more characteristics may be determined by performing a single regression analysis of the voltage output and current output recorded over the entire discharging of the battery.

Alternatively, the one or more characteristics may determined by combining separate analyses of a plurality of portions of the recorded voltage output and current output. For instance, the discharge profile may comprise several discharge cycles (e.g. each comprising a period of discharging and period of no discharging) and a separate regression analysis may be performed for the voltage output and current output for each discharge cycle (e.g. to determine ECM parameters of the battery during that discharge cycle). The results of the separate analyses may be combined to determine the one or more characteristics (e.g. by calculating a mean or median of ECM parameters determined for each cycle). Determining the one or more characteristics using separate analyses of a plurality of portions of the recorded voltage output and current output may lead to more accurate results and/or may be less computationally intensive to perform. Separately analysing portions of the discharging may also allow changes in battery characteristics as the battery discharges to be identified.

In some embodiments, one or more portions of the recorded voltage output and current output may not be used to determine the one or more characteristics of the battery. For instance, portions corresponding to a final discharge cycle (e.g. when the battery reaches a cutoff voltage) may be disregarded as not being representative of normal battery operation.

The discharge profile may comprise a pattern of discharge currents. The timing and/or magnitude of the discharge currents may be selected based on the one or more nominal properties. For instance, the timing and magnitude of discharge currents in the discharge profile may be selected to discharge the battery over a particular duration based on a nominal capacity of the battery. In some embodiments, the discharge profile is selected based on a nominal capacity, a remaining capacity, a nominal internal resistance and/or a chemistry of the battery. The discharge profile may comprise continuously discharging the battery at a constant or varying discharge current. The discharge profile may comprise periods of discharging and periods of no discharging (e.g. in which the controllable load acts as an open circuit).

In a set of embodiments, the discharge profile comprises a series of discharge current pulses. The discharge current pulses may be separated by periods of reduced or zero discharge current. The series of discharge current pulses may comprise one or more constant discharge current pulses (i.e. in which the discharge current does not change during the pulse). In some embodiments, each discharge current pulse has the same duration and/or the same discharge current. In other embodiments, the series of discharge current pulses may comprise discharge current pulses with different durations and/or discharge currents. The number, duration and/or magnitude of the discharge current pulses may be selected based on the one or more nominal properties.

Discharging the battery according to a predetermined profile may facilitate the extraction of useful information about the battery. For instance, the way in which the output voltage of the battery reacts to a particular discharge current or the way in which the output voltage of the battery recovers during a period of no discharging may be analysed to determine the one or more characteristics. The discharge profile may be used to determine the one or more characteristics. For instance, a battery model may be used to predict a voltage output over the discharge based on the discharge profile, with the model parameters refined by minimising the error between this predicted voltage output and the recorded voltage output.

In a set of embodiments, a temperature of the battery is also recorded as the battery is being discharged. The battery characterisation system may comprise a temperature sensor arranged to measure a temperature of the battery (e.g. the temperature of a chemical cell in said battery). The temperature sensor may be integral to the battery (e.g. the battery may comprise an integral temperature sensor such as an NTC resistor). In some such embodiments, the battery characterisation system comprises an input for receiving temperature data from a temperature sensor integral to the battery. Additionally or alternatively, a separate temperature sensor may be used.

The recorded temperature may be used when determining the one or more characteristics of the battery. Additionally or alternatively, the one or more characteristics of the battery may be associated with a temperature or an average temperature recorded when the battery was being discharged. Producing temperature-specific characterisation information may be particularly useful as it enables more appropriate and accurate characterisation information to be applied when the battery is subsequently used (e.g. when estimating the SOC of the battery).

The battery characterisation system may be used to determine characteristics of the battery under different conditions (e.g. with different battery temperatures). In a set of embodiments, the discharge profile comprises a first discharge profile and the battery characterisation system is arranged:
to select a second discharge profile based on said one or more nominal properties;
to control the controllable load to discharge the battery according to the first discharge profile when the battery is at a first temperature;
to record the voltage output measured by the voltage sensor and a current output from the battery as the battery is being discharged at the first temperature;
to control the controllable load to discharge the battery according to a second discharge profile when the battery is at a second temperature;
to record the voltage output measured by the voltage sensor and a current output from the battery as the battery is being discharged at the second temperature; and
to determine one or more characteristics of the battery using said recorded voltage outputs and current outputs.

The first and second discharge profiles may be the same. In other words, the battery characterisation system may be arranged simply to perform the same process to determine one or characteristics of the battery in different conditions.

The first and second temperatures may represent expected maximum and minimum operating temperatures for the battery.

The battery characterisation system may additionally be used to determine characteristics of the battery in one or more further temperatures (e.g. a temperature in the middle of an expected operational temperature range).

The battery characterisation system may be arranged to control the temperature of the battery. For instance, the battery characterisation system may comprise one or more heating or cooling elements arranged to heat or cool the battery. The battery characterisation system may be arranged to heat or cool the battery to the first and/or second temperature.

In a set of embodiments, the battery characterisation system comprises a battery interface device arranged to be connected to the battery. For instance, the battery interface device may comprise first and second input terminals for connecting to positive and negative terminals of the battery. The battery interface device may be arranged to connect to a plurality of different types of batteries (e.g. different shapes, sizes and other nominal properties).

The battery interface device may comprise the voltage sensor and/or a current sensor and/or a temperature sensor. The battery interface device may comprise the controllable load. The battery interface device may comprise a clock arranged to produce time information, e.g. to facilitate recording a time-stamped record of the voltage output and/or the current output.

The battery interface device may be arranged to record the voltage output and/or the current output and/or the temperature (e.g. a time-stamped time series of the voltage output and/or the current output and/or the temperature). For instance, the battery interface device may comprise a memory to which the voltage output and/or the current output and/or the temperature is recorded. Additionally or alternatively, the battery interface device may be arranged to forward the voltage output and/or the current output and/or the temperature to another component of the battery characterisation system (e.g. a processing device).

The battery interface device may be arranged to carry out one or more data processing procedures on the output voltage and/or output current and/or temperature. The battery interface device may be arranged to record and/or forward the output voltage and/or output current and/or temperature in a predetermined format (e.g. in a format optimal for determining the one or more characteristics).

In a set of embodiments, the battery characterisation system comprises a processing device arranged to determine the one or more characteristics of the battery using said recorded voltage output and current output. The processing device may comprise a computer (e.g. a PC). The processing device may be provided remotely to other components of the battery characterisation system (e.g. a remote server providing a cloud processing service). The processing device may be connected to a battery interface device and/or a user interface via one or more data connections. The battery interface device or the processing device may provide the user interface.

In a set of embodiments, the battery interface device comprises:
the controllable load; and
the voltage sensor;
wherein the battery interface device is arranged to:
control the controllable load to discharge the battery according to the discharge profile;
record the voltage output measured by the voltage sensor and the current output from the battery as the battery is being discharged; and
send said recorded voltage output and current output to a processing device for determining one or more characteristics of the battery using said recorded voltage output and current.

In some embodiments, a single physical device comprises a battery interface device, a processing device and a user interface. Alternatively, one or more of these devices is provided separately.

The processing device may be arranged to select the discharge profile. Alternatively, the battery interface device may be arranged to select the discharge profile.

This battery interface device is considered to be independently inventive and so according to a fourth aspect of the present invention there is provided a battery interface device comprising:
a controllable load arranged to be connected to a battery; and
a voltage sensor arranged to measure a voltage output from said battery; wherein the battery interface device is arranged to:
control the controllable load to discharge the battery according to a discharge profile selected based on one or more nominal properties of said battery;
record the voltage output measured by the voltage sensor and a current output from the battery as the battery is being discharged; and
send said recorded voltage output and current output to a processing device for determining one or more characteristics of the battery using said recorded voltage output and current output.

According to a fifth aspect of the present invention there is provided computer software comprising instructions that, when executed by a processing system, cause the processing system to:
control a controllable load to discharge a battery according to a discharge profile selected based on one or more nominal properties of said battery;
record a voltage output from said battery and a current output from said battery as the battery is being discharged; and
send said recorded voltage output and current output to a processing device for determining one or more characteristics of the battery using said recorded voltage output and current output.

The battery interface device thus provides an integrated solution for gathering information about the behaviour of a battery as it is being discharged, which can be used in combination with a processing device (e.g. standard PC) to accurately characterise a battery. The battery interface device may be suitable for connecting a plurality of types of battery, to provide a convenient way to characterise a range of batteries quickly and accurately.

Features of any aspect or embodiment described herein may, wherever appropriate, be applied to any other aspect or embodiment described herein. In particular, features and functions described above with reference to the first, second and third aspects may, where appropriate, be applied to the battery interface device of the fourth aspects. Where reference is made to different embodiments, it should be understood that these are not necessarily distinct but may overlap.

### BRIEF DESCRIPTION OF THE DRAWINGS

One or more non-limiting examples will now be described, by way of example only, and with reference to the accompanying figures in which:

FIG. 1 is a block diagram of a battery characterisation system according to an embodiment of the present invention;

FIGS. 2 and 3 show example discharge current output and voltage output waveforms;

FIG. 4 shows an example of a battery equivalent circuit model; and

FIGS. 5 and 6 are graphs illustrating steps in a process for determining parameters of said battery equivalent circuit model.

### DETAILED DESCRIPTION

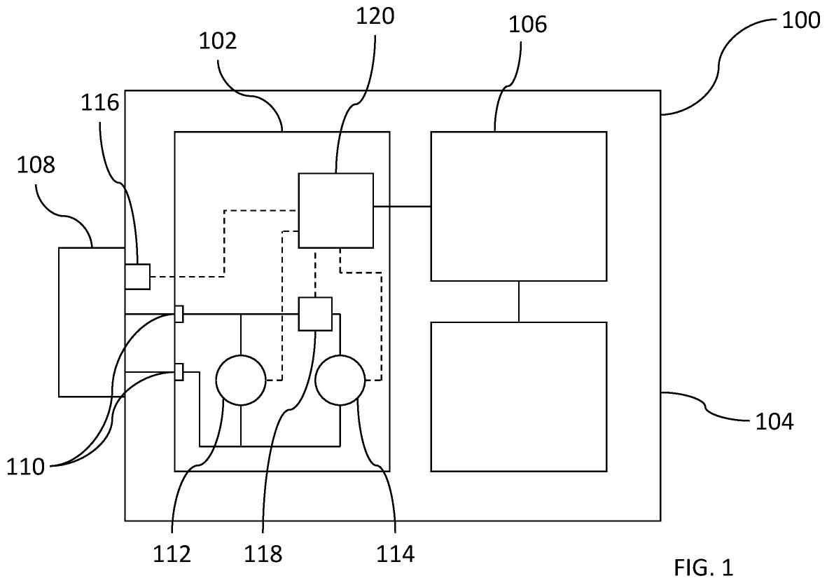

FIG. 1 shows a battery characterisation system 100 comprising a battery interface device 102, a user interface 104 and a processing device 106. In this embodiment the processing device 106 is a personal computer (PC).

The system 100 is used to characterise a battery 108. The battery 108 is connected to the battery interface device 102. The battery interface device 102 comprises a pair of connection terminals 110 that are connected to positive and negative terminals of the battery 108 (not shown). The battery interface device 102 also comprises a voltage sensor 112, a current sensor 114, a temperature sensor 116, a controllable load 118 and a controller 120.

To characterise the battery 108, a user connects the battery 108 to the connection terminals 110 and inputs nominal battery properties using the user interface 104 (e.g. via a GUI). In this embodiment the battery is a LiPo battery. The nominal battery properties input by the user are a nominal capacity (e.g. 1000 mAh), a discharge cutoff voltage (e.g. 3 V), a charge cutoff voltage (e.g. 4.2 V) and a nominal battery voltage (e.g. 3.7 V).

Based on the nominal battery properties, the processing device 106 selects a discharge profile suitable for characterising the battery 108 (e.g. using a look-up table). The discharge profile chosen in this example involves a series of discharge cycles made up of discharge current pulses at a fixed discharge current of 52 mA separated by longer periods of no current load, until the battery 108 reaches the discharge cutoff voltage.

The processing device 106 controls the battery interface device 102 to perform a single discharge of the battery 108 according to the selected discharge profile. The battery interface device 102 controls the controllable load to provide a 52 mA current load to the battery 108 during the discharge pulses and zero load (e.g. an open circuit) between the pulses.

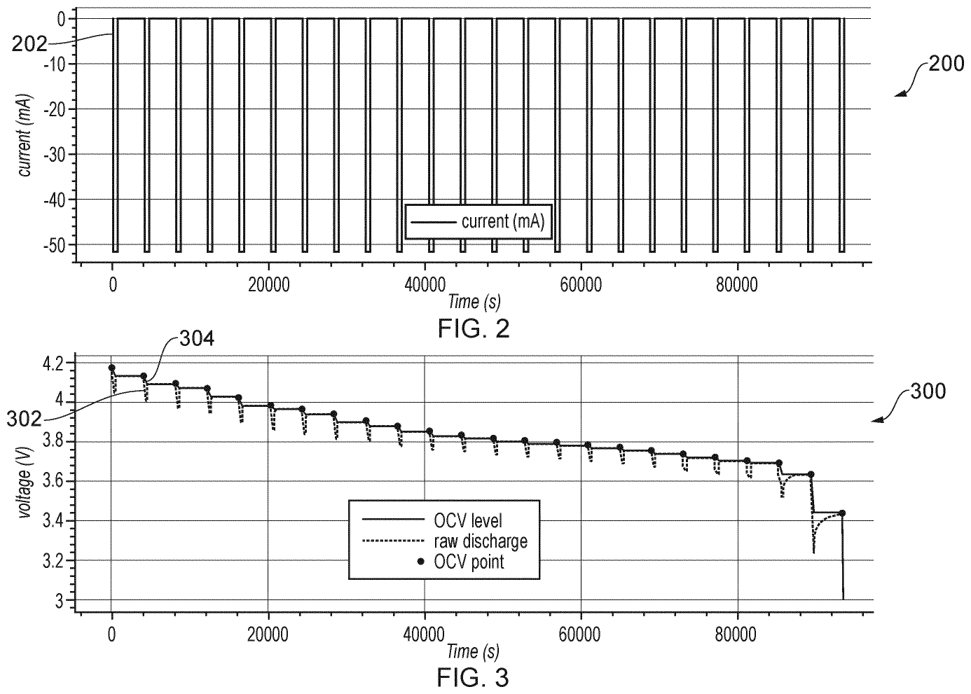

As the battery 108 is discharged according to the discharge profile, the battery interface device 102 records the voltage, current and temperature data from the voltage sensor 112, current sensor 114 and temperature sensor 116 respectively, with corresponding time-stamps. FIG. 2 shows a graph 200 of the recorded current 202 over the discharge, showing the 52 mA pulses of the discharge profile. FIG. 3 shows a graph 300 of the recorded terminal voltage 302 over the discharge along with an indication of the open circuit voltage (OCV) 304 over the discharge. The OCV 304 during the periods of no load is estimated as the value of the terminal voltage 302 just before the next current pulse begins, with a linear decrease during each current pulse.

The graph 300 shows how the terminal voltage 302 falls during the periods of load, and then recovers during the periods of no load. The terminal voltage 302 and, correspondingly, the open circuit voltage 304, steadily decline as the battery 108 is discharged.

The battery interface device 102 sends the recorded data to the processing device 106. Once the battery 108 has been fully discharged (e.g. the voltage 302 falls below the discharge cutoff voltage), the processing device 106 uses the recorded data to determine one or more characteristics of the battery 108.

The characteristics determined by the processing device 106 are parameters of a battery equivalent circuit model (ECM) that emulates the behaviour of the battery 108. The chosen ECM depends on the battery chemistry and associated electrical properties.

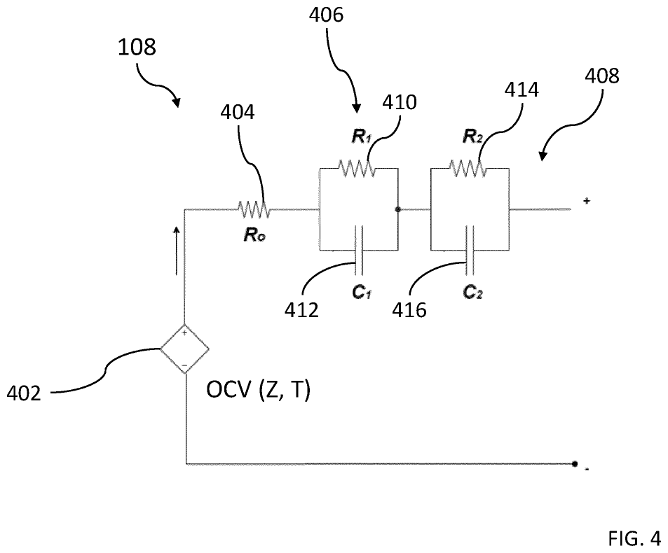

The battery ECM is shown in FIG. 4. In this model, the battery 108 comprises a voltage source 402 having an open circuit voltage OCV. The OCV is a function of the state of charge Z and the temperature T of the battery 108. The model of the battery 108 also comprises an internal series resistor 404 with resistance R₀, a first RC element 406 and a second RC element 408. The internal series resistor 404 models the instantaneous polarization of the battery voltage and the first and second RC elements 406, 408 model diffusion voltage characteristics of the battery 108. The first RC element 406 comprises a first resistor 410 having resistance R₁ in parallel with a first capacitor 412 having capacitance C₁. Similarly, the second RC element 408 comprises a second resistor 414 having resistance R₂ in parallel with a second capacitor 416 having capacitance C₂.

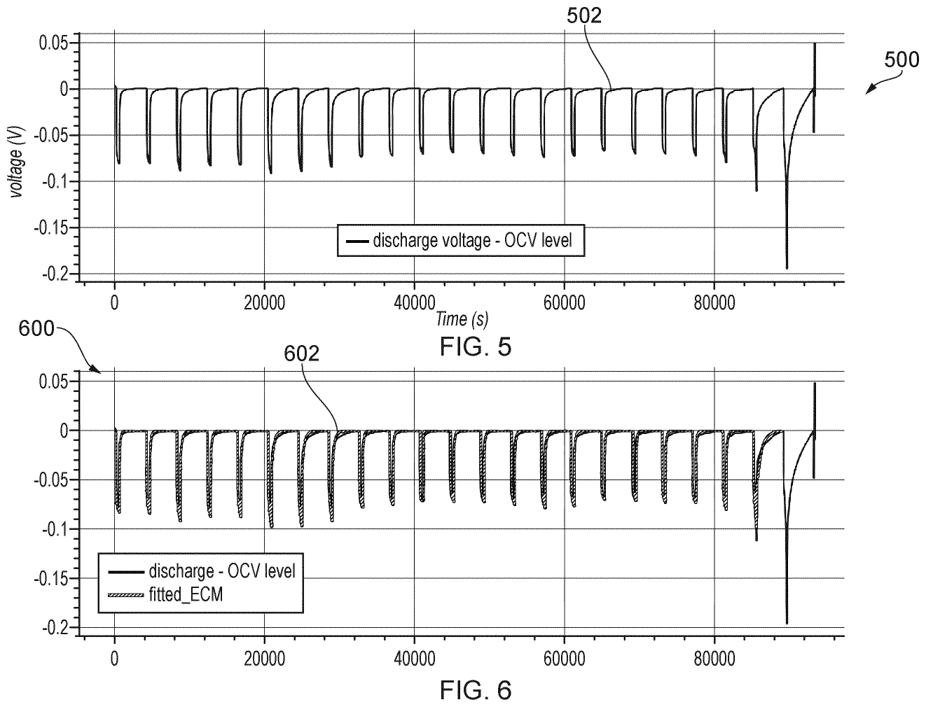

As explained below with reference to FIGS. 5 and 6, the processing device 106 determines an estimate of the internal resistance R₀ and the resistances and capacitances R₁, R₂, C₁, C₂ of the RC elements 406, 408 using the recorded data and the discharge profile. The processing device 106 uses the optimises the parameters of the model (i.e. the resistances and capacitances) to minimise the error between a modelled output voltage for the discharge profile and the recorded output voltage.

First, the processing device 106 calculates the difference between the terminal voltage 302 and the OCV 304 over the discharge. FIG. 5 shows a graph 500 of this difference 502 over the discharge.

The processing device 106 then applies a curve-fitting algorithm to the difference 502 to find the ECM parameters. As illustrated in FIG. 6, the processing device 106 finds the ECM parameters which minimise the error between a modelled difference 602 (i.e. generated using the battery ECM) and the actual difference 502.

The processing device 106 applies the curve-fitting algorithm separately to the data from each discharge cycle (i.e. one discharge current pulse and one subsequent period of no load).

The processing device 106 averages the determined ECM parameters for all but the final discharge cycle to produce average ECM parameters for the battery 108. Averaging (e.g. calculating a mean or median) the ECM parameters determined for a series of discharge cycles (e.g. rather than simply curve-fitting the entire discharge cycle) may lead to more accurate results and/or may be less computationally intensive to perform. Determining ECM parameters for each discharge cycle also makes it possible to analyse how the battery characteristics evolve during battery discharge (i.e. for different battery SOCs).

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A battery characterisation system for determining one or more characteristics of a battery comprising:
a controllable load arranged to be connected to a battery; and
a voltage sensor arranged to measure a voltage output from said battery;
wherein the battery characterisation system is arranged to:
receive information identifying one or more nominal properties of said battery select a discharge profile based on said one or more nominal properties;
control the controllable load to discharge said battery according to said discharge profile;
record the voltage output measured by the voltage sensor and a current output from the battery as the battery is being discharged; and
determine one or more characteristics of the battery using said recorded voltage output and current output.

2. The battery characterisation system as claimed in claim 1, wherein the one or more nominal properties comprises a nominal capacity, a discharge cutoff voltage, a charge cutoff voltage, a nominal voltage, a charge termination current and/or a battery chemistry.

3. The battery characterisation system as claimed in claim 1, comprising a user interface arranged to receive the information identifying the one or more nominal properties from a user.

4. The battery characterisation system as claimed in claim 1, wherein recording the voltage output and/or the current output comprises producing a time series of voltage and/or current information.

5. The battery characterisation system as claimed in claim 1, wherein the one or more characteristics of the battery are one or more parameters of a battery model.

6. The battery characterisation system as claimed in claim 1, arranged to determine the one or more characteristics using a regression analysis technique.

7. The battery characterisation system as claimed in claim 1, wherein the discharge profile comprises a pattern of discharge currents, the timing and/or magnitude of said discharge currents being selected based on the one or more nominal properties.

8. The battery characterisation system as claimed in claim 1, comprising a temperature sensor arranged to measure a temperature of the battery.

9. The battery characterisation system as claimed in claim 1, comprising an input for receiving temperature data from a temperature sensor integral to the battery.

10. The battery characterisation system as claimed in claim 1, comprising a battery interface device, wherein the battery interface device comprises the voltage sensor and the controllable load.

11. The battery characterisation system as claimed in claim 10, wherein the battery interface device is arranged to:
control the controllable load to discharge the battery according to the discharge profile;
record the voltage output measured by the voltage sensor and the current output from the battery as the battery is being discharged; and
send said recorded voltage output and current output to a processing device for determining one or more characteristics of the battery using said recorded voltage output and current.

12. The battery characterisation system as claimed in claim 1, comprising a processing device arranged to determine the one or more characteristics of the battery using said recorded voltage output and current output.

13. The battery characterisation system as claimed in claim 12, wherein the processing device comprises a computer.

14. A method of characterising a battery comprising:
receiving information identifying one or more nominal properties of a battery;
selecting a discharge profile based on said one or more nominal properties;
controlling a load connected to a battery to discharge said battery according to said discharge profile;
recording a voltage output from said battery and a current output from said battery during said discharging; and
determining one or more characteristics of the battery using said recorded voltage output and current output.

15. (canceled)

16. A battery interface device comprising:
a controllable load arranged to be connected to a battery; and
a voltage sensor arranged to measure a voltage output from said battery;
wherein the battery interface device is arranged to:
control the controllable load to discharge the battery according to a discharge profile selected based on one or more nominal properties of said battery;
to record the voltage output measured by the voltage sensor and a current output from the battery as the battery is being discharged; and
to send said recorded voltage output and current output to a processing device for determining one or more characteristics of the battery using said recorded voltage output and current output.

17. (canceled)
